(19) United States
(12) Patent Application Publication
(10) Pub. No.: US 2025/0379188 A1
(43) Pub. Date: Dec. 11, 2025

(54) HIGH-BANDWIDTH MEMORY (HBM) PACKAGE-ON-PACKAGE (POP) DYNAMIC RANDOM-ACCESS MEMORY (DRAM) WITH SEMICONDUCTOR PILLARS

(71) Applicant: QUALCOMM Incorporated, San Diego, CA (US)

(72) Inventors: Mustafa BADAROGLU, San Diego, CA (US); Jonghae KIM, San Diego, CA (US); Zhongze WANG, San Diego, CA (US); Woo Tag KANG, San Diego, CA (US); Jihong CHOI, San Diego, CA (US); Hyun LEE, San Diego, CA (US); Giridhar NALLAPATI, San Diego, CA (US); Periannan CHIDAMBARAM, San Diego, CA (US)

(21) Appl. No.: 18/739,185

(22) Filed: Jun. 10, 2024

(51) Int. Cl. H01L 25/065; H01L 21/48; H01L 21/56; H01L 23/31; H01L 23/367; H01L 23/373; H01L 23/498; H10B 80/00

(52) U.S. Cl. CPC H01L 25/0657; H01L 21/486; H01L 21/563; H01L 21/565; H01L 23/3128; H01L 23/367; H01L 23/373; H01L 23/49827; H10B 80/00; H01L 2225/0651

(57) ABSTRACT

A system-in-package (SIP) is described. The SIP includes a first package substrate supporting a logic die. The SIP also includes a second package substrate supporting a stack of memory dies. The SIP further includes semiconductor pillar bricks coupled between the first package substrate and the second package substrate.

### BACKGROUND

### Field

Aspects of the present disclosure relate to integrated circuits (ICs) and, more particularly, to a high-bandwidth memory (HBM) package-on-package (PoP) dynamic random-access memory (DRAM) with semiconductor pillars.

### Background

Memory is a vital component for wireless communications devices. For example, a mobile phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of a processor workload. A semiconductor memory device solution for providing a high-capacity, low-latency, and high-bandwidth memory is an existing goal for system designers.

Semiconductor memory devices include, for example, a static random-access memory (SRAM) and a dynamic random-access memory (DRAM). In practice, memory intensive applications (e.g., artificial intelligence (AI)) consume extensive amounts of DRAM. State of the art high-bandwidth memory (HBM) DRAM provides advantages in performance and power for memory-demanding workloads such as generative-AI. Edge computing involves high-bandwidth DRAM integration solutions for AI workloads at a reduced form factor for mobile phone integration. Unfortunately, reduced form factor dimensions and thermal limitations significantly restrict the introduction of high-bandwidth memory subsystems for mobile/edge products. Placement of a thicker die at the bottom of package-on-package (PoP) restricts the scaling of conductive pillar pitch due to aspect ratio restrictions of conductive pillars utilized to provide package-to-package vertical connections. Therefore, a solution for an HBM PoP integration in mobile/edge devices is desired.

### SUMMARY

A system-in-package (SIP) is described. The SIP includes a first package substrate supporting a logic die. The SIP also includes a second package substrate supporting a stack of memory dies. The SIP further includes semiconductor pillar bricks coupled between the first package substrate and the second package substrate.

A method of forming a system-on-chip (SoC) package utilizing a high-bandwidth memory (HBM) package-on-package (POP) integration is described. The method includes flip-chip bonding of semiconductor pillar bricks to a back side of a wafer substrate of a memory wafer. The method also includes stacking the memory wafer on a logic wafer contacted using the semiconductor pillar bricks. The memory wafer supporting a stack of memory dies. Additionally, the logic wafer supporting a logic die. The method further includes singulating the stacked memory wafer and the logic wafer.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-chip (SoC), including a high-bandwidth memory (HBM) package-on-package (PoP) integration utilizing semiconductor pillar bricks, in accordance with certain aspects of the present disclosure.

FIG. 2 shows a cross-sectional view of a stacked integrated circuit (IC) package of the host system-on-chip (SoC) of FIG. 1.

FIG. 3 shows a cross-sectional view illustrating the stacked integrated circuit (IC) package of FIG. 2, incorporated into a wireless device, according to one aspect of the present disclosure.

FIGS. 4A and 4B are block diagrams illustrating a system-on-chip (SoC) package having a high-bandwidth memory (HBM) package-on-package (PoP) integration utilizing semiconductor pillar bricks, according to various aspects of the present disclosure.

FIG. 5A and 5B are block diagrams illustrating a system-on-chip (SoC) package having a high-bandwidth memory (HBM) package-on-package (PoP) integration utilizing semiconductor pillar bricks, according to various aspects of the present disclosure.

FIGS. 6A-6H are cross-sectional diagrams illustrating chip first and chip last processes for initial formation of the system-on-chip (SoC) package of FIG. 4A, according to various aspects of the present disclosure.

FIGS. 7A-7D further illustrate the process of forming the system-on-chip (SoC) package of FIG. 4A, including the high-bandwidth memory (HBM) package-on-package (PoP) integration utilizing the semiconductor pillar bricks, following the chip first and chip last processing for forming the memory package as shown in FIGS. 6A-6H.

FIG. 8 is a process flow diagram illustrating a method for forming a system-on-chip (SoC) package utilizing a high-bandwidth memory (HBM) package-on-package (PoP) integration, according to various aspects of the present disclosure.

FIG. 9 is a block diagram showing an exemplary wireless communications system, in which an aspect of the present disclosure may be advantageously employed.

FIG. 10 is a block diagram illustrating a design workstation used for circuit, layout, and logic design of a semiconductor component such as the high-bandwidth memory (HBM) package-on-package (PoP) integration disclosed herein.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

Memory is a vital component for wireless communications devices. For example, a mobile phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of a processor workload. A semiconductor memory device solution for providing a high-capacity, low-latency, and high-bandwidth memory is an existing goal for system designers.

Semiconductor memory devices include, for example, dynamic random-access memory (DRAM). A DRAM memory cell includes one transistor and one capacitor, thereby providing a high degree of integration. DRAM-on-logic, however, is hindered by temperature envelope limitations of DRAM on hotspots on the processor(s) of an SoC. Integrating DRAM on hot compute logic including the processor(s) is problematic because this hot compute logic prevents cooling of the DRAM junction temperatures. These limitations have led to industry implementation of DRAM in a side-by-side configuration with the processor of the hot compute logic.

In practice, memory intensive applications (e.g., artificial intelligence (AI)) consume extensive amounts of DRAM. State of the art high-bandwidth memory (HBM) DRAM provides advantages in performance and power for memory-demanding workloads such as generative-AI. Edge computing involves high-bandwidth DRAM integration solutions for AI workloads at a reduced form factor for mobile phone integration. Unfortunately, reduced form factor dimensions and thermal limitations significantly restrict the introduction of high-bandwidth memory subsystems for mobile/edge products. Placement of a thicker die at the bottom of package-on-package (PoP) devices restricts the scaling of conductive pillar pitch due to aspect ratio restrictions of conductive pillars utilized to provide package-to-package vertical connections.

In practice, high thermal logic necessitates increasing the height of a logic package for improved thermal performance. An increased thickness of the logic device improves thermal conduction. This increased thickness involves an increased pitch between conductive pillars to accommodate the larger height due to aspect ratio limitations. Additionally, accessing high-bandwidth memory (HBM) in a PoP configuration is limited by the amount of vertical conductive pillars supplying vertical connections between a logic package and an HBM package stacked on the logic package. A tight pitch for increasing the number of vertical conductive pillars is difficult due to the aspect ratio limitations. Therefore, a solution for an HBM POP integration in mobile/edge devices is desired.

Various aspects of the present disclosure provide a high-bandwidth memory (HBM) package-on-package (PoP) integration. The process flow for fabrication of an HBM PoP integration may further include formation of a vertical semiconductor bridge high-bandwidth connection to an HBM package. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably. Similarly, the terms “chip,” “chiplet,” and “die” may be used interchangeably.

Various aspects of the present disclosure are directed to utilization of semiconductor pillar bricks as a vertically connected bridge between a first fan-out (FO)/interposer/substrate supporting a logic die (e.g., a logic package) to a second FO/interposer/substrate supporting a stack of memory dies (e.g., a memory package). In various aspects of the present disclosure, the stack of memory dies are composed of a high-bandwidth memory (HBM) dynamic random-access memory (DRAM) stack. These aspects of the present disclosure enable a tighter pitch for the vertical connections between a logic package and a memory package placed in a PoP configuration with the use of semiconductor pillar bricks. These aspects of the present disclosure support a high thermal conduction path from a logic package to an outer package by the incorporation of semiconductor pillar bricks incorporating through-vias. Additionally, a simplified integration flow prevents the semiconductor pillar bricks from being concurrently planarized with a logic die, resulting in a significant yield improvement from the simplified integration flow. The semiconductor pillar bricks may be beneficially re-used for any product.

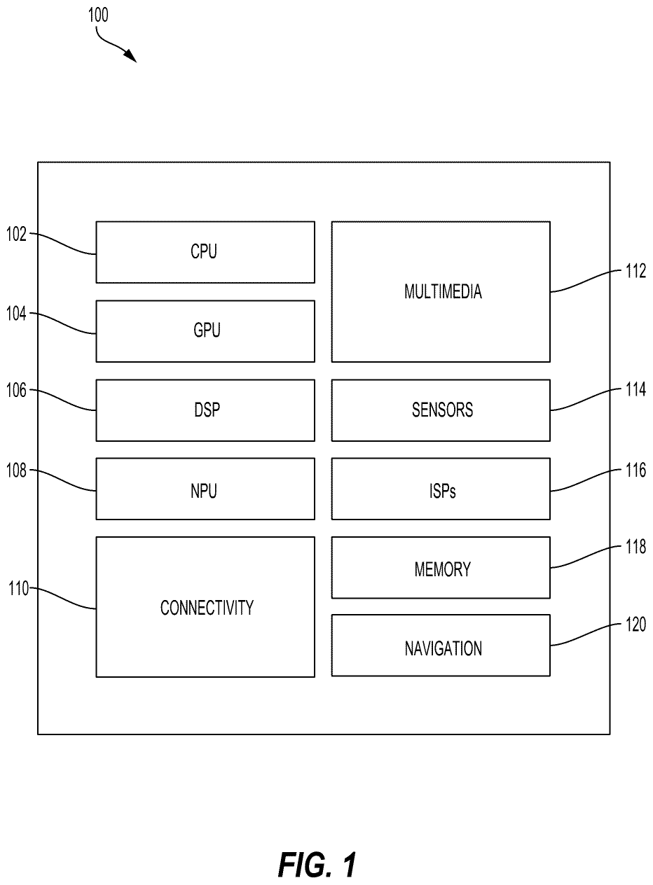

FIG. 1 illustrates an example implementation of a host system-on-chip (SoC) 100, which includes a high-bandwidth memory (HBM) package-on-package (PoP) integration utilizing semiconductor pillar bricks, in accordance with certain aspects of the present disclosure. The host SoC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

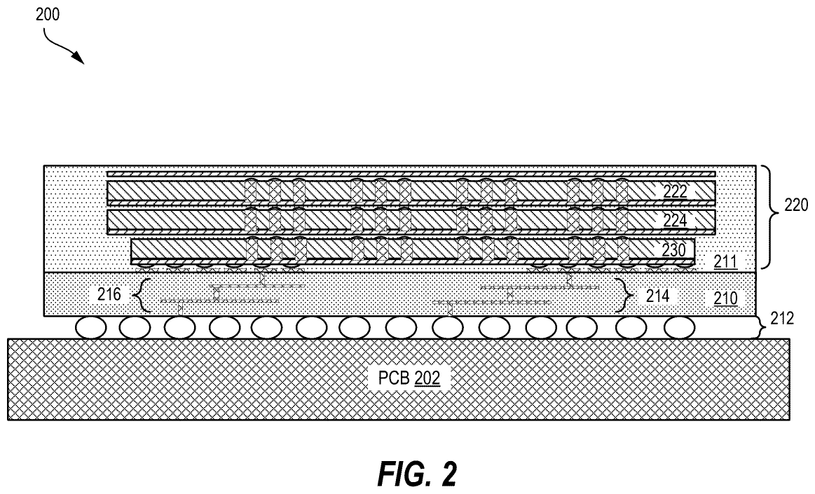

FIG. 2 shows a cross-sectional view of a stacked integrated circuit (IC) package 200 of the host system-on-chip (SoC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the host SoC 100 of FIG. 1.

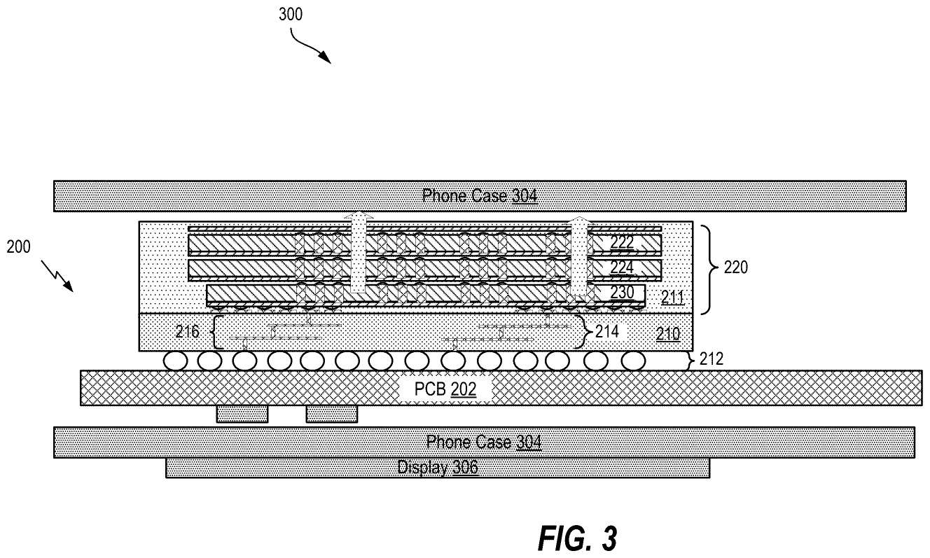

FIG. 3 shows a cross-sectional view illustrating the stacked integrated circuit (IC) package 200 of FIG. 2, incorporated into a wireless device 300, according to one aspect of the present disclosure. As described, the wireless device 300 may include, but is not limited to, a smartphone, tablet, handheld device, or other limited form factor device configured for 5G NR/6G communications. Representatively, the stacked IC package 200 is within a phone case 304, including a display 306.

In practice, high thermal logic necessitates increasing the height of a logic package in the stacked integrated circuit (IC) package 200 of FIG. 2 for improved thermal performance. An increased thickness of the logic device improves thermal conduction. This increased thickness involves an increased pitch between conductive pillars to accommodate the larger height due to aspect ratio limitations. Additionally, accessing high-bandwidth memory (HBM) in a package-on-package (PoP) configuration is limited by the amount of vertical conductive pillars supplying vertical connections between a logic package and an HBM package stacked on the logic package.

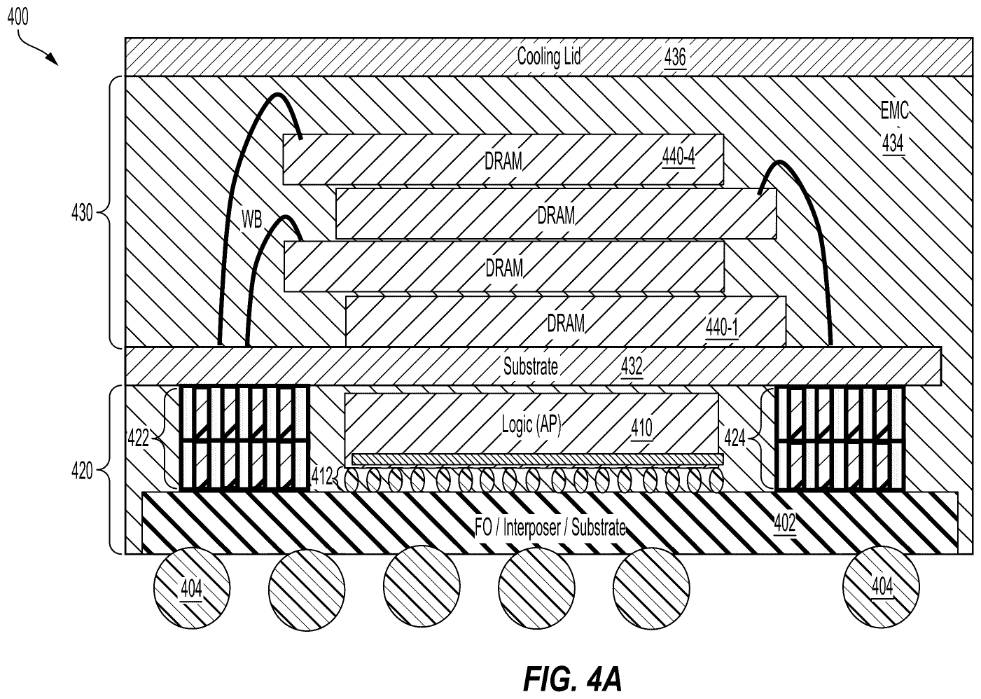

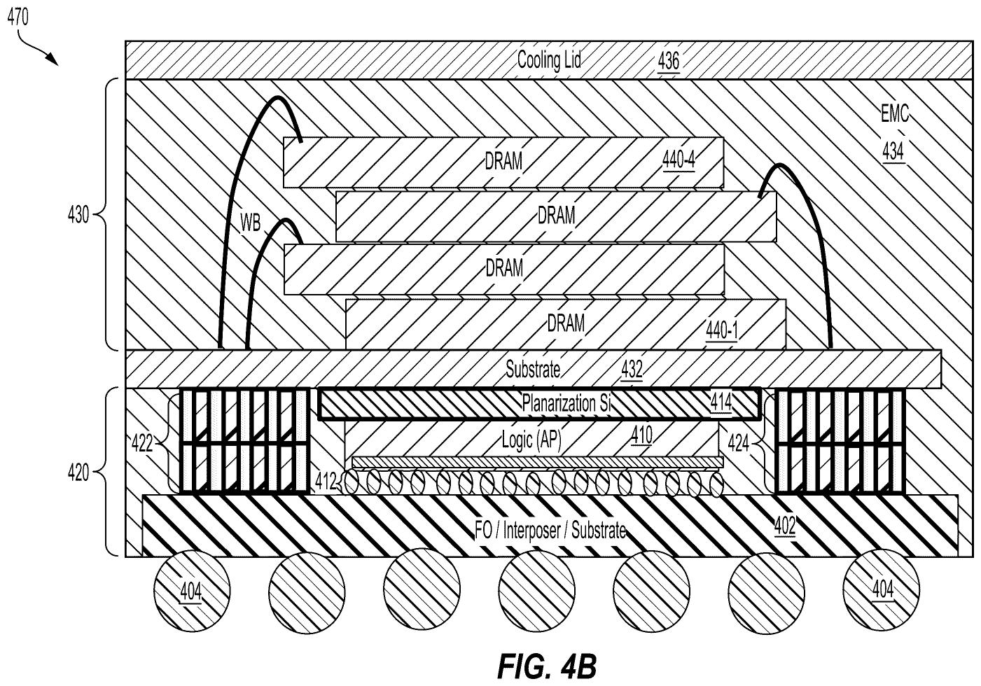

A tight-pitch for increasing the number of vertical conductive pillars is difficult due to the aspect ratio limitations. Therefore, a solution for a high-bandwidth memory (HBM) package-on-package (PoP) integration in mobile/edge devices is desired. In various aspects of the present disclosure, an HBM PoP integration utilizing semiconductor pillar bricks is integrated in the stacked IC package 200 for providing a vertical connection bridge to support 3D chip stacking, for example, as shown in FIGS. 4A to 7D. For example, as shown in FIGS. 4A to 7D, one or more than one vertically connected semiconductor pillar(s) could be stacked on top of each other to reach the desired bottom package thickness while enabling tighter pitch vertical connections to the top HBM memory package.

FIGS. 4A and 4B are block diagrams illustrating a system-on-chip (SoC) package having a high-bandwidth memory (HBM) package-on-package (PoP) integration utilizing semiconductor pillar bricks, according to various aspects of the present disclosure. The SoC package may be referred to as a system-in-package (SIP) in some implementations. As shown in FIG. 4A, an SoC package 400 includes a first package substrate 402 (e.g., fan-out (FO), interposer, substrate, redistribution layer (RDL)) having package bumps 404 on a backside and micro-bumps 412 for supporting a frontside of a logic die 410 (e.g., application processor (AP)).

In this configuration, the first package substrate 402 and the logic die 410 form a logic package 420, in which conventional conductive pillars (e.g., copper (Cu) pillars) are replaced with a first semiconductor pillar brick 422 and a second semiconductor pillar brick 424. According to various aspects of the present disclosure, the first semiconductor pillar brick 422 and the second semiconductor pillar brick 424 are composed of vertically stacked silicon blocks having aligned through silicon vias (TSVs).

In these aspects of the present disclosure, the first semiconductor pillar brick 422 and the second semiconductor pillar brick 424 provide fine-pitch vertical connections to support a vertical silicon bridge for enabling a high-bandwidth connection with a memory package 430. Although described in reference to semiconductor materials (e.g., silicon), the first semiconductor pillar brick 422 and the second semiconductor pillar brick 424 may be composed of a silicon block, including through silicon vias (TSVs), a ceramic material, including through ceramic vias (TCVs), a glass material, including through glass vias (TGVs), or other like material.

As shown in FIG. 4A, the SoC package 400 includes a second package substrate 432 (e.g., fan-out (FO), interposer, substrate, redistribution layer (RDL)) stacked on the first semiconductor pillar brick 422 and the second semiconductor pillar brick 424. The second package substrate 432 supports a memory stack 440 (440-1, . . . , 440-4) coupled to the second package substrate 432 through wire-bonds (WB). For example, the memory stack 440 is composed of a high-bandwidth memory (HBM) core stack of dynamic random-access memory (DRAM) dies or another like wide input/output (IO) device. In this configuration, the memory package 430 is composed of the memory stack 440 supported by the second package substrate 432.

According to various aspects of the present disclosure, the first semiconductor pillar brick 422 and the second semiconductor pillar brick 424 vertically connect the first package substrate 402 supporting the logic die 410 to the second package substrate 432 supporting the memory stack 440. As shown in FIG. 4A, the first semiconductor pillar brick 422 and the second semiconductor pillar brick 424 provide a tighter pitch for the vertical connections between the logic package 420 and the memory package 430 in the PoP configuration with the use of semiconductor brick pillars of TSVs. Additionally, the SoC package 400 includes an embedded molding compound (EMC) 434 on the logic package 420 and the memory package 430 and supporting a cooling lid 436. Various aspects of the present disclosure create a high thermal conduction path from the logic package 420 to an outer package by incorporating semiconductor pillars with TSVs (e.g., 422 and 424) and forming the EMC 434 using a thermally conductive material.

As shown in FIG. 4B, an SoC package 470 is like the SoC package 400 of FIG. 4A and is described using similar reference numbers. The SoC package 470 in FIG. 4B includes an optional planarization layer 414, that is omitted from the SoC package 400 shown in FIG. 4A. In some aspects of the present disclosure, the optional planarization layer 414 (e.g., silicon (Si)) is utilized as a mechanical support for the second package substrate 432 to prevent substrate warpage and to guide planarization of the bottom package top surface. Additionally, the optional planarization layer 414 may operate as a thermal spreading layer for heat dissipation from the logic die 410.

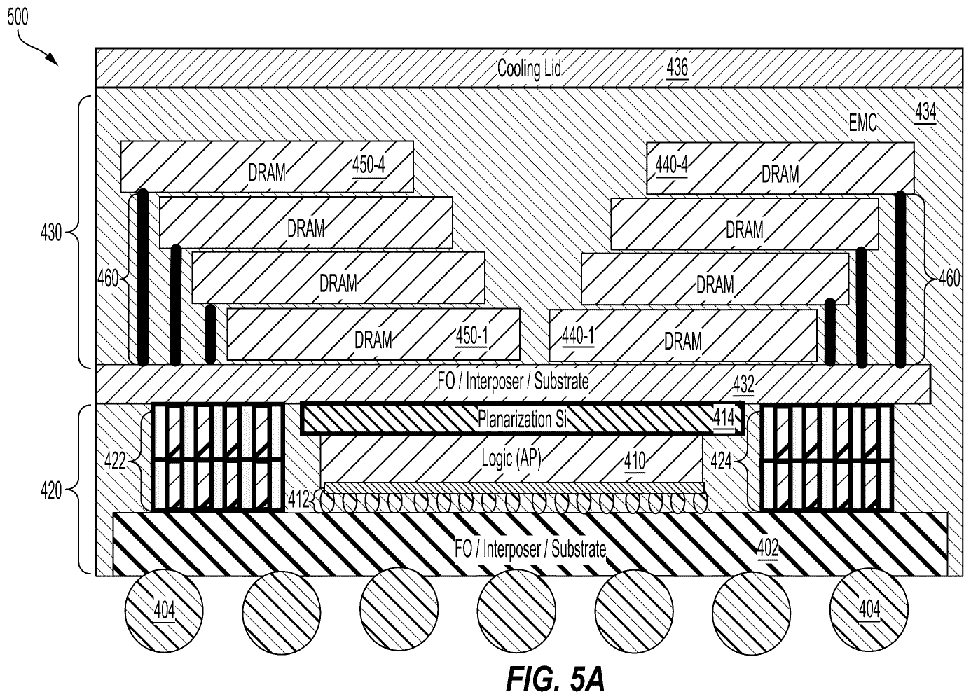

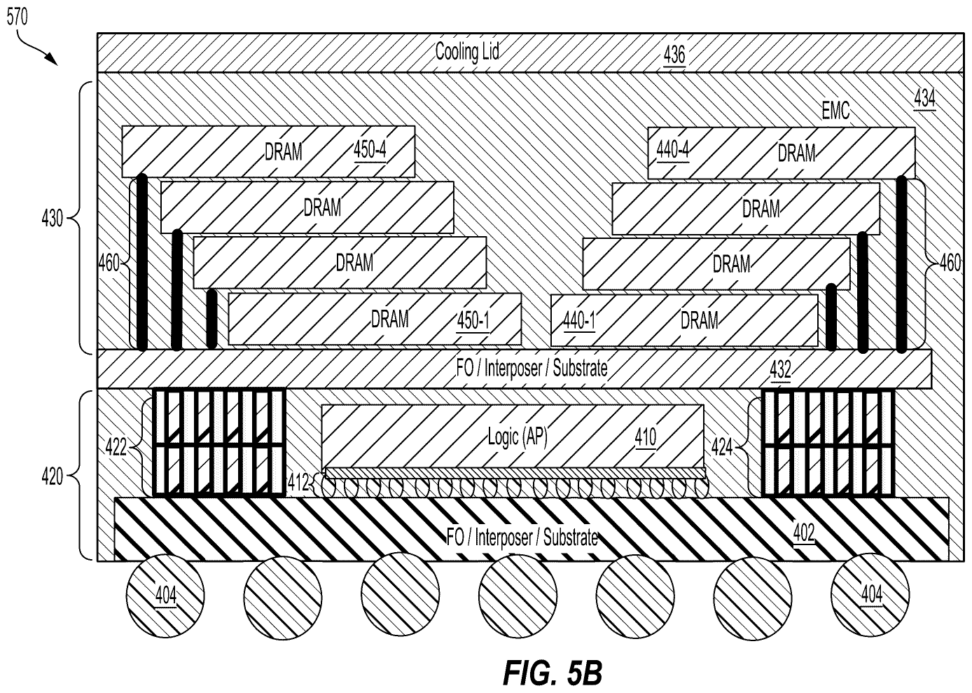

FIG. 5A and 5B are block diagrams illustrating a system-on-chip (SoC) package having a high-bandwidth memory (HBM) package-on-package (PoP) integration utilizing semiconductor pillar bricks, according to various aspects of the present disclosure. As shown in FIG. 5A, an SoC package 500 is like the SoC package 400 of FIG. 4A and is described using similar reference numbers. In various aspects of the present disclosure, the SoC package 500 supports a fine pitch configuration of the memory package 430 by utilizing vertical pillar connections between the memory dies of the memory stack 440 and a memory stack 450 (450-1, . . . 450-4) and the second package substrate 432.

In various aspects of the present disclosure, the memory stack 440 and the memory stack 450 utilize vertical through mold vias (TMVs) 460 to contact the second package substrate 432. As shown in FIG. 5A, the second package substrate 432 is configured for fine-pitch signaling to support high-bandwidth communication through the fine-pitch vertical connections provided by the first semiconductor pillar brick 422 and the second semiconductor pillar brick 424. The fine-pitch signaling configuration of the second package substrate 432, however, may lead to an increased threat of substrate warpage.

In some aspects of the present disclosure, an optional planarization layer 414 (e.g., silicon (Si)) is utilized as a mechanical support for the second package substrate 432 to prevent substrate warpage and to guide planarization of the bottom package top surface. Additionally, the optional planarization layer 414 may operate as a thermal spreading layer for heat dissipation from the logic die 410. As shown in FIG. 5B, an SoC package 570 is like the SoC package 500 of FIG. 5A and is described using similar reference numbers. The SoC package 570 in FIG. 5B omits the optional planarization layer 414 shown in FIG. 5A.

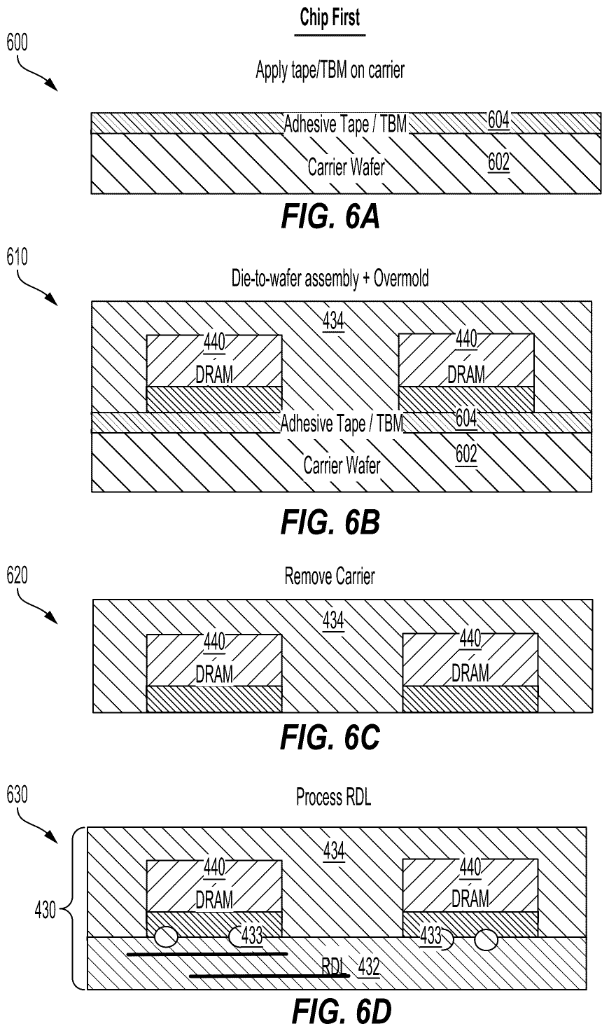

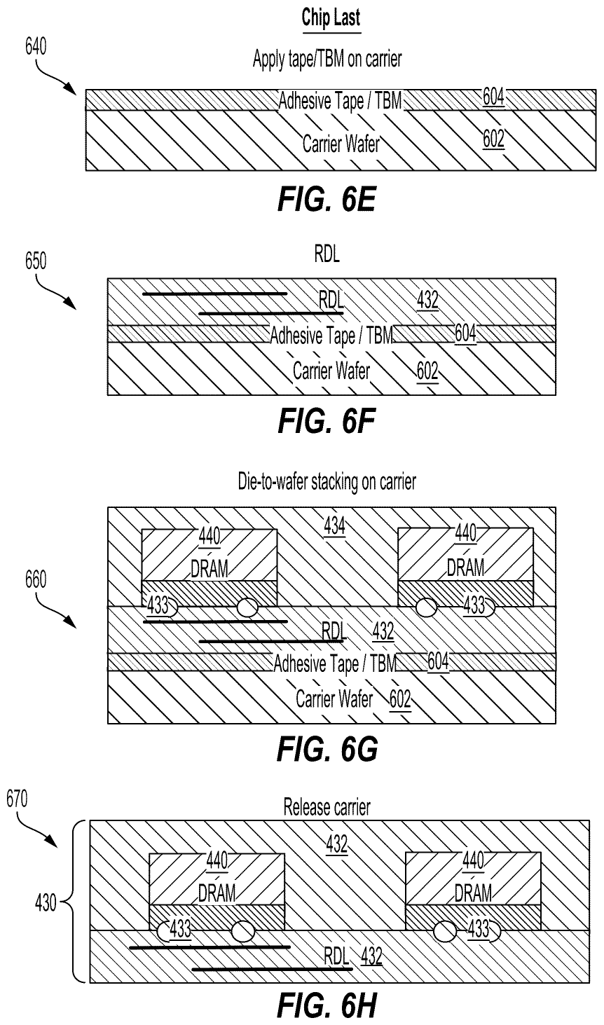

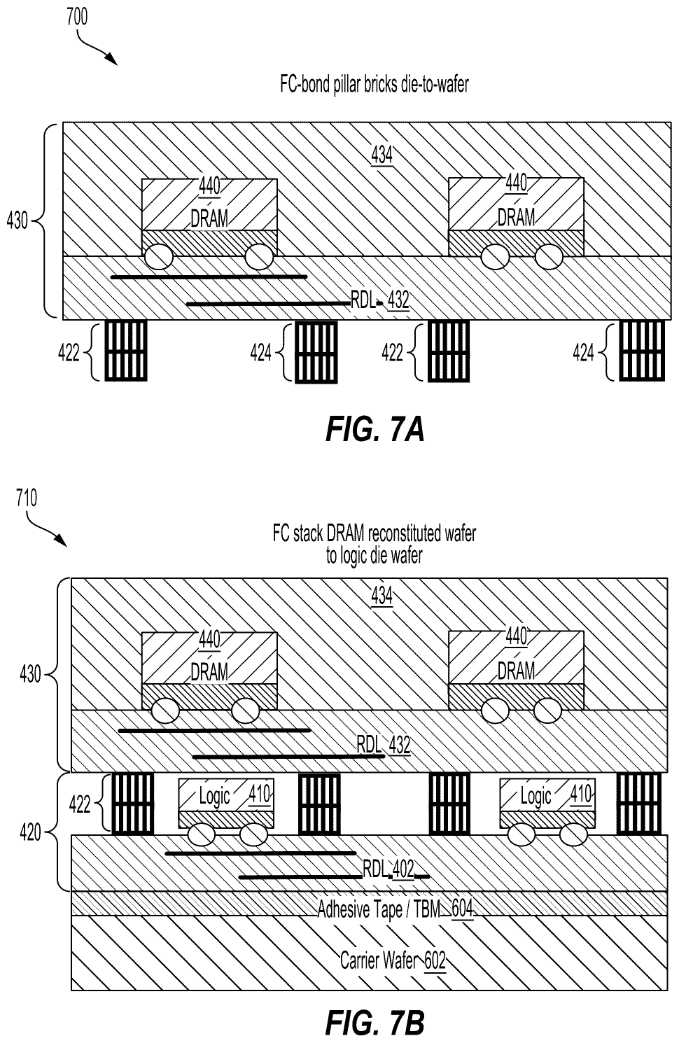

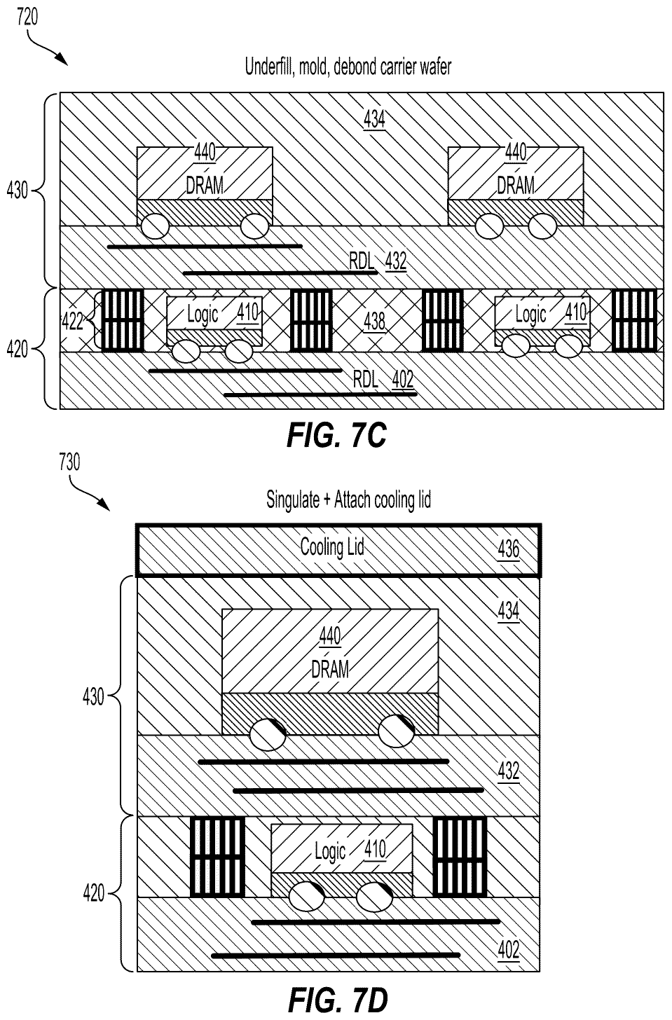

Implementation of a process for forming a system-on-chip (SoC) package that includes the high-bandwidth memory (HBM) package-on-package (PoP) integration utilizing semiconductor pillar bricks is shown in FIGS. 6A-7D. FIGS. 6A-6H are cross-sectional diagrams illustrating chip first and chip last processes for initial formation of the SoC package 400 of FIG. 4A, according to various aspects of the present disclosure.

FIG. 6A illustrates a first step 600 for forming the memory package 430 of the SoC package 400 of FIG. 4A, according to various aspects of the present disclosure. The first step 600 of a chip first process illustrates application of an adhesive tape 604 to a carrier wafer 602.

FIG. 6B illustrates a second step 610 for forming the memory package 430 of the SoC package 400 of FIG. 4A, according to various aspects of the present disclosure. The second step 610 of the chip first process illustrates a die-to-wafer assembly, in which the memory stack 440 is secured to the adhesive tape 604. Once the memory stack 440 is secured, an over-mold deposition forms the EMC 434.

FIG. 6C illustrates a third step 620 for forming the memory package 430 of the SoC package 400 of FIG. 4A, according to various aspects of the present disclosure. The third step 620 of the chip first process illustrates removal of the carrier wafer 602 and the adhesive tape 604.

FIG. 6D illustrates a fourth step 630 for forming the memory package 430 of the SoC package 400 of FIG. 4A, according to various aspects of the present disclosure. The fourth step 630 of the chip first process illustrates formation of the second package substrate 432, which is shown as a redistribution layer (RDL) contacted to the memory stack 440 through micro-bumps 433. In this example, the micro-bumps 433 could also be used to support known good die (KGD) testing of the memory package 430 prior to the RDL build-up. As described above, the second package substrate 432 may be implemented as a fan-out (FO), an interposer, an RDL, or another like package substrate.

FIG. 6E illustrates a first step 640 for forming the memory package 430 of the SoC package 400 of FIG. 4A, according to various aspects of the present disclosure. The first step 640 of the chip last process illustrates application of an adhesive tape 604 to a carrier wafer 602.

FIG. 6F illustrates a second step 650 for forming the memory package 430 of the SoC package 400 of FIG. 4A, according to various aspects of the present disclosure. The second step 650 of the chip last process illustrates formation of the second package substrate 432, which is shown as a redistribution layer (RDL) on the adhesive tape 604. As noted above, the second package substrate 432 may be implemented as a fan-out (FO), an interposer, an RDL, or another like package substrate.

FIG. 6G illustrates a third step 660 for forming the memory package 430 of the SoC package 400 of FIG. 4A, according to various aspects of the present disclosure. The third step 660 of the chip last process illustrates a die-to-wafer stacking on the carrier wafer 602, in which the memory stack 440 is secured to the second package substrate 432, which is shown as an RDL. In this example, an over-mold deposition forms the EMC 434 prior to securing the memory stack 440 to the second package substrate 432.

FIG. 6H illustrates a fourth step 670 for forming the memory package 430 of the SoC package 400 of FIG. 4A, according to various aspects of the present disclosure. The fourth step 670 of the chip last process illustrates removal of the carrier wafer 602 and the adhesive tape 604 to complete formation of the memory package 430.

FIGS. 7A-7D further illustrate the process of forming the SoC package 400 of FIG. 4A, including the high-bandwidth memory (HBM) package-on-package (PoP) integration utilizing the semiconductor pillar bricks, following the chip first and chip last processing for forming the memory package 430, as shown in FIGS. 6A-6H.

FIG. 7A illustrates a first step 700 for forming the SoC package 400 of FIG. 4A, having the HBM POP integration utilizing the semiconductor pillar bricks. At the first step 700, a flip-chip (FC) bonding of the first semiconductor pillar brick 422 and the second semiconductor pillar brick 424 to a backside of the second package substrate 432 (e.g., a wafer substrate) of the memory package 430 (e.g., a memory wafer) is performed.

FIG. 7B illustrates a second step 710 for forming the SoC package 400 of FIG. 4A, having the HBM POP integration utilizing the semiconductor pillar bricks, according to various aspects of the present disclosure. The second step 710 illustrates flip-chip (FC) stacking of the memory package 430 to the logic package 420 (e.g., a logic wafer) using the first semiconductor pillar brick 422 and the second semiconductor pillar brick 424.

FIG. 7C illustrates a third step 720 for forming the SoC package 400 of FIG. 4A, having the HBM POP integration utilizing the semiconductor pillar bricks, according to various aspects of the present disclosure. The third step 720 illustrates formation of an underfill embedded molding compound 438, followed by debonding of the carrier wafer 602.

FIG. 7D illustrates a fourth step 730 for forming the SoC package 400 of FIG. 4A, having the HBM PoP integration utilizing the semiconductor pillar bricks, according to various aspects of the present disclosure. The fourth step 730 illustrates singulation and attachment of the cooling lid 436 to complete formation of the SoC package 400. According to various aspects of the present disclosure, stacking of the logic package 420 and the memory package 430 is performed using micro-bump stacking/die-to-die hybrid bonding/wafer to wafer hybrid bonding, or the like. Additionally, separate thermal dissipation devices/substrates (e.g., the optional planarization layer 414) may be utilized to compensate for hot spot areas of the logic die 410.

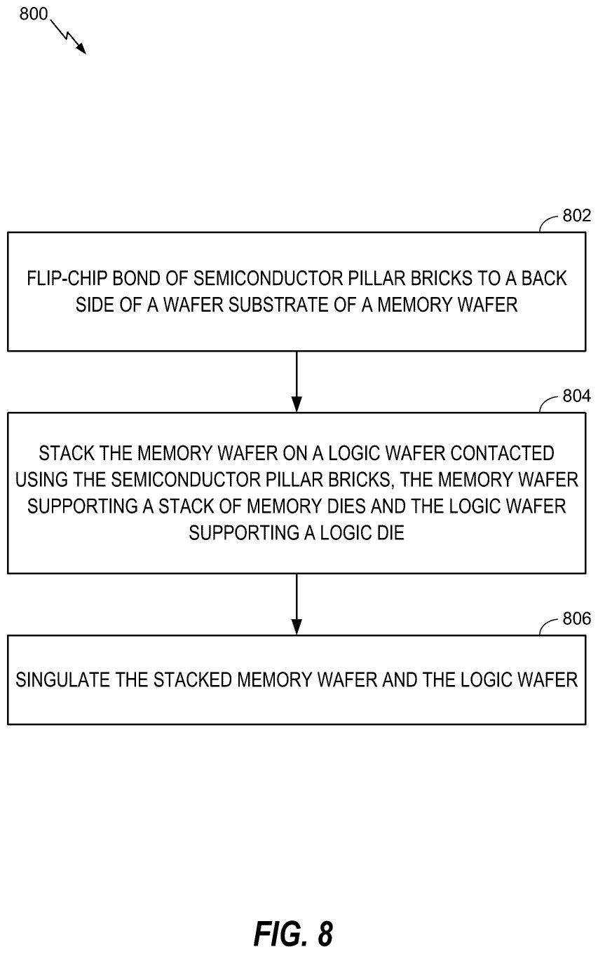

FIG. 8 is a process flow diagram illustrating a method 800 for forming a system-on-chip (SoC) package utilizing a high-bandwidth memory (HBM) package-on-package (PoP) integration, according to various aspects of the present disclosure. The method 800 begins at block 802, in which flip-chip bonding of semiconductor pillar bricks is performed on a back side of a wafer substrate of a memory wafer. For example, FIG. 7A illustrates a first step 700 for forming the SoC package 400 of FIG. 4A, having the HBM POP integration utilizing the semiconductor pillar bricks. At the first step 700, flip-chip (FC) bonding of the first semiconductor pillar brick 422 and the second semiconductor pillar brick 424 to a backside of the second package substrate 432 (e.g., a wafer substrate) of the memory package 430 (e.g., a memory wafer) is performed.

At block 804, the memory wafer is stacked on a logic wafer contacted using the semiconductor pillar bricks, in which the memory wafer supports a stack of memory dies and the logic wafer supports a logic die. For example, FIG. 7B illustrates a second step 710 for forming the SoC package 400 of FIG. 4A, having the HBM PoP integration utilizing the semiconductor pillar bricks, according to various aspects of the present disclosure. The second step 710 illustrates flip-chip (FC) stacking of the memory package 430 to the logic package 420 (e.g., a logic wafer) using the first semiconductor pillar brick 422 and the second semiconductor pillar brick 424.

At block 806, the stacked memory wafer and the logic wafer are singulated. For example, FIG. 7D illustrates a fourth step 730 for forming the SoC package 400 of FIG. 4A, having the HBM POP integration utilizing the semiconductor pillar bricks, according to various aspects of the present disclosure. The fourth step 730 illustrates singulation and attachment of the cooling lid 436 to complete formation of the SoC package 400. According to various aspects of the present disclosure, stacking of the logic package 420 and the memory package 430 is performed using micro-bump stacking/die-to-die hybrid bonding/wafer to wafer hybrid bonding, or the like. Additionally, separate thermal dissipation devices/substrates (e.g., the optional planarization layer 414) may be utilized to compensate for hot spot areas of the logic die 410.

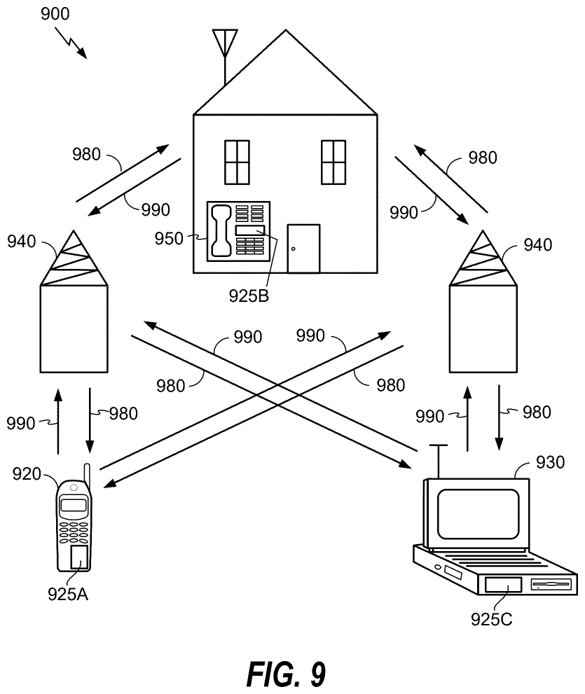

FIG. 9 is a block diagram showing an exemplary wireless communications system 900, in which an aspect of the present disclosure may be advantageously employed. For purposes of illustration, FIG. 9 shows three remote units 920, 930, and 950, and two base stations 940. It will be recognized that wireless communications systems may have many more remote units and base stations. Remote units 920, 930, and 950 include integrated circuit (IC) devices 925A, 925B, and 925C that include the disclosed high-bandwidth memory (HBM) package-on-package (PoP) integration. It will be recognized that other devices may also include the disclosed HBM PoP integration, such as the base stations, switching devices, and network equipment. FIG. 9 shows forward link signals 980 from the base stations 940 to the remote units 920, 930, and 950, and reverse link signals 990 from the remote units 920, 930, and 950 to the base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 9 illustrates remote units according to the aspects of the present disclosure, the disclosure is not limited to these exemplary illustrated units. Aspects of the present disclosure may be suitably employed in many devices, which include the disclosed HBM POP integration.

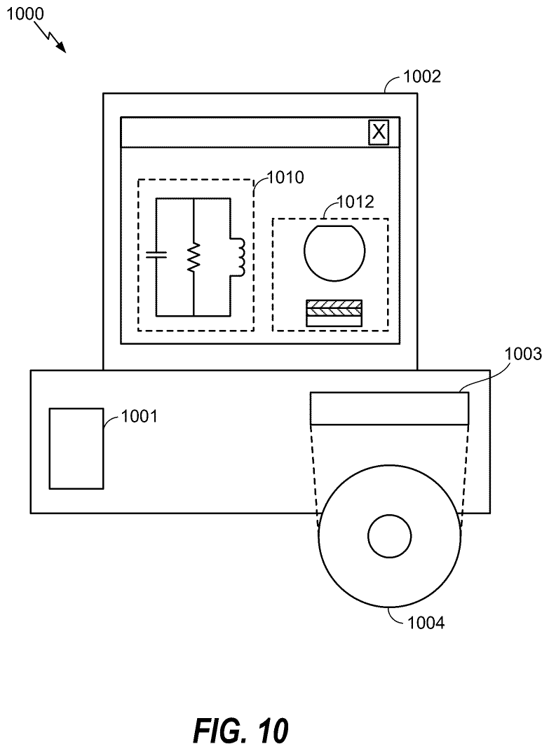

FIG. 10 is a block diagram illustrating a design workstation 1000 used for circuit, layout, and logic design of a semiconductor component, such as the high-bandwidth memory (HBM) package-on-package (PoP) integration disclosed above. The design workstation 1000 includes a hard disk 1001 containing operating system software, support files, and design software such as Cadence or OrCAD. The design workstation 1000 also includes a display 1002 to facilitate design of a circuit 1010 or a semiconductor component 1012, such as the HBM PoP integration. A storage medium 1004 is provided for tangibly storing the design of the circuit 1010 or the semiconductor component 1012 (e.g., the HBM PoP integration). The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

Implementation examples are described in the following numbered clauses:
1. A system-in-package (SIP), comprising:
   a first package substrate supporting a logic die;
   a second package substrate supporting a stack of memory dies; and
   semiconductor pillar bricks coupled between the first package substrate and the second package substrate.
2. The SIP of clause 1, in which the semiconductor pillar bricks comprise:
   a silicon block; and
   through silicon vias (TSVs) extending through the silicon block.
3. The SIP of any of clauses 1 or 2, further comprising wire-bonds coupled between the stack of memory dies and the second package substrate.
4. The SIP of any of clauses 1-3, further comprising:
   an embedded molding compound (EMC) on the stack of memory dies and the second package substrate; and
   through mold vias (TMVs) extending between the stack of memory dies and the second package substrate.
5. The SIP of clause 4, further comprising a cooling lid on the embedded molding compound (EMC).
6. The SIP of clause 4, in which the embedded molding compound (EMC) comprises a thermally conductive material.
7. The SIP of any of clauses 1-6, further comprising a planarization layer between the logic die and the second package substrate.
8. The SIP of any of clauses 1-7, in which the first package substrate comprises a redistribution layer (RDL).
9. The SIP of any of clauses 1-8, in which the second package substrate comprises a redistribution layer (RDL).
10. The SIP of any of clauses 1-9, in which the stack of memory dies comprises a high-bandwidth memory (HBM) dynamic random-access memory (DRAM) stack.
11. A method of forming a system-on-chip (SoC) package utilizing a high-bandwidth memory (HBM) package-on-package (PoP) integration, the method comprising:
   flip-chip bonding of semiconductor pillar bricks to a back side of a wafer substrate of a memory wafer;
   stacking the memory wafer on a logic wafer contacted using the semiconductor pillar bricks, the memory wafer supporting a stack of memory dies and the logic wafer supporting a logic die; and
   singulating the stacked memory wafer and the logic wafer.
12. The method of any of clause 11, in which the semiconductor pillar bricks comprise:
   a silicon block; and
   through silicon vias (TSVs) extending through the silicon block.
13. The method of any of clauses 11 or 12, further comprising coupling wire-bonds between the stack of memory dies and the memory wafer.
14. The method of any of clauses 11-13, further comprising:
   depositing an embedded molding compound (EMC) on the stack of memory dies and the memory wafer; and
   forming through mold vias (TMVs) extending between the stack of memory dies and the memory wafer.
15. The method of clause 14, further comprising forming a cooling lid on the embedded molding compound (EMC).
16. The method of clause 14, in which the embedded molding compound (EMC) comprises a thermally conductive material.
17. The method of any of clauses 11-19, further comprising forming a planarization layer between the logic die and the memory wafer.
18. The method of any of clauses 11-19, in which the wafer substrate comprises a redistribution layer (RDL).
19. The method of any of clauses 11-19, in which the memory wafer comprises a redistribution layer (RDL).
20. The method of any of clauses 11-19, in which the stack of memory dies comprises a high-bandwidth memory (HBM) dynamic random-access memory (DRAM) stack.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random-access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. A system-in-package (SIP), comprising:
a first package substrate supporting a logic die;
a second package substrate supporting a stack of memory dies; and
semiconductor pillar bricks coupled between the first package substrate and the second package substrate.

2. The SIP of claim 1, in which the semiconductor pillar bricks comprise:
a silicon block; and
through silicon vias (TSVs) extending through the silicon block.

3. The SIP of claim 1, further comprising wire-bonds coupled between the stack of memory dies and the second package substrate.

4. The SIP of claim 1, further comprising:
an embedded molding compound (EMC) on the stack of memory dies and the second package substrate; and
through mold vias (TMVs) extending between the stack of memory dies and the second package substrate.

5. The SIP of claim 4, further comprising a cooling lid on the embedded molding compound (EMC).

6. The SIP of claim 4, in which the embedded molding compound (EMC) comprises a thermally conductive material.

7. The SIP of claim 1, further comprising a planarization layer between the logic die and the second package substrate.

8. The SIP of claim 1, in which the first package substrate comprises a redistribution layer (RDL).

9. The SIP of claim 1, in which the second package substrate comprises a redistribution layer (RDL).

10. The SIP of claim 1, in which the stack of memory dies comprises a high-bandwidth memory (HBM) dynamic random-access memory (DRAM) stack.

11. A method of forming a system-on-chip (SoC) package utilizing a high-bandwidth memory (HBM) package-on-package (POP) integration, the method comprising:
flip-chip bonding of semiconductor pillar bricks to a back side of a wafer substrate of a memory wafer;
stacking the memory wafer on a logic wafer contacted using the semiconductor pillar bricks, the memory wafer supporting a stack of memory dies and the logic wafer supporting a logic die; and
singulating the stacked memory wafer and the logic wafer.

12. The method of claim 11, in which the semiconductor pillar bricks comprise:
a silicon block; and
through silicon vias (TSVs) extending through the silicon block.

13. The method of claim 11, further comprising coupling wire-bonds between the stack of memory dies and the memory wafer.

14. The method of claim 11, further comprising:
depositing an embedded molding compound (EMC) on the stack of memory dies and the memory wafer; and
forming through mold vias (TMVs) extending between the stack of memory dies and the memory wafer.

15. The method of claim 14, further comprising forming a cooling lid on the embedded molding compound (EMC).

16. The method of claim 14, in which the embedded molding compound (EMC) comprises a thermally conductive material.

17. The method of claim 11, further comprising forming a planarization layer between the logic die and the memory wafer.

18. The method of claim 11, in which the wafer substrate comprises a redistribution layer (RDL).

19. The method of claim 11, in which the memory wafer comprises a redistribution layer (RDL).

20. The method of claim 11, in which the stack of memory dies comprises a high-bandwidth memory (HBM) dynamic random-access memory (DRAM) stack.
